(19) United States
(12) Patent Application Publication
(10) Pub. No.: US 2012/0221179 A1
(43) Pub. Date: Aug. 30, 2012

(54) UNMANNED AERIAL VEHICLE AND METHOD FOR ADJUSTING FLIGHT DIRECTION OF THE SAME

(75) Inventors: HOU-HSIEN LEE, Tu-Cheng (TW); CHANG-JUNG LEE, Tu-Cheng (TW); CHIH-PING LO, Tu-Cheng (TW)

(73) Assignee: HON HAI PRECISION INDUSTRY CO., LTD., Tu-Cheng (TW)

(21) Appl. No.: 13/167,721

(22) Filed: Jun. 24, 2011

(30) Foreign Application Priority Data
Feb. 24, 2011 (TW) 100106260

(51) Int. Cl. G05D 1/00; G01R 33/02; G01C 17/00

(52) U.S. Cl. 701/3

(57) ABSTRACT

A method for adjusting a flight direction of an unmanned aerial vehicle (UAV) using a control device receives a first direction of the control device and a control command of the UAV, obtains a second direction of the UAV, and calculates an angle deviation between the first direction and the second direction. The method further adjusts the control command of the UAV according to the angle deviation to obtain an adjusted control command, and controls a flight direction of the UAV according to the adjusted control command

### BACKGROUND

1. Technical Field

Embodiments of the present disclosure relate to helicopter control technology, and particularly to an unmanned aerial vehicle (UAV) and method for adjusting a flight direction of the UAV using a control device.

2. Description of Related Art

UAVs have been used to perform security surveillance by capturing images of a number of monitored scenes, and sending the captured images to a monitor computer. A flight direction of the UAV needs to be changed using a special controller. If an administrator wants to change the flight direction of the UAV to the left, the administrator has to move a control lever of the special controller towards the left. However, if the flight direction of the UAV is opposite to a direction of the special controller, the administrator has to move the control lever of the special controller towards the right, to change the flight direction of the UAV to the left. Accordingly, it is inefficient to control the UAV, and a wrong control operation of the UAV may be implemented because of human error during the operation of the special controller. Therefore, an efficient method for adjusting a flight direction of the UAV is desired.

### BRIEF DESCRIPTION OF THE DRAWINGS

FIG. 1 is a block diagram of one embodiment of an unmanned aerial vehicle (UAV).

FIG. 2 is a block diagram of one embodiment of a control command adjustment system in the UAV.

FIG. 3 is a flowchart of one embodiment of a method for adjusting a flight direction of the UAV using a control device.

FIG. 4 is a schematic diagram of one embodiment of a first direction of the control device and a second direction of the UAV.

FIG. 5 is a schematic diagram of one embodiment of an angle deviation between the first direction of the control device and the second direction of the UAV.

### DETAILED DESCRIPTION

All of the processes described below may be embodied in, and fully automated via, functional code modules executed by one or more general purpose electronic devices or processors. The code modules may be stored in any type of non-transitory readable medium or other storage device. Some or all of the methods may alternatively be embodied in specialized hardware. Depending on the embodiment, the non-transitory readable medium may be a hard disk drive, a compact disc, a digital video disc, a tape drive or other suitable storage medium.

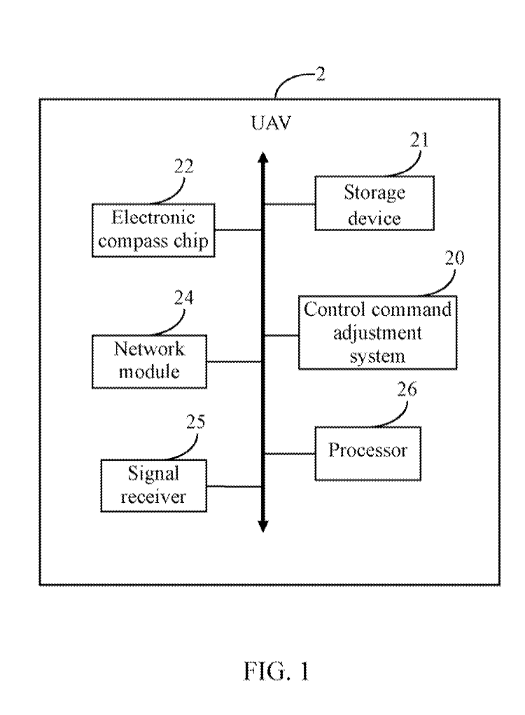

FIG. 1 is a block diagram of one embodiment of an unmanned aerial vehicle (UAV) 2. In one embodiment, the UAV 2 includes a control command adjustment system 20, a storage device 21, an electronic compass chip 22, a network module 24, a signal receiver 25, and at least one processor 26. The control command adjustment system 20 may obtain a direction of a control device from a communication with the UAV 2, and adjust a flight direction of the UAV 2 according to the obtained direction of the control device. A detailed description will be given in the following paragraphs.

In one embodiment, the UAV 2 is controlled using a control device. The control device has a control lever to control the flight direction of the UAV 2. For example, the control lever of the control device may be moved left to control the UAV 2 to move westwards.

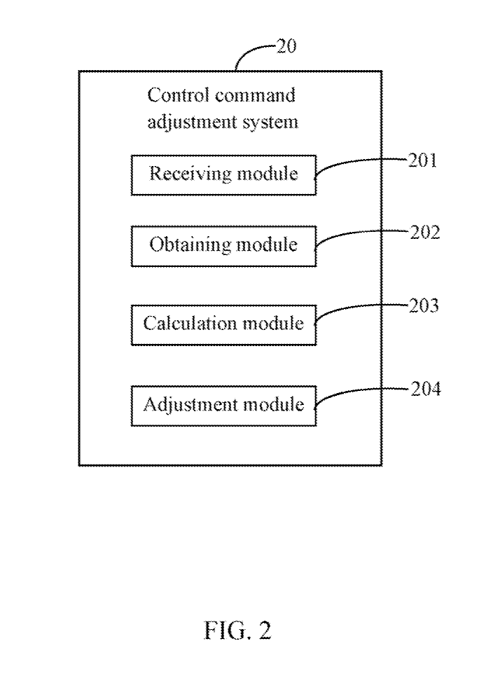

FIG. 2 is a block diagram of one embodiment of the control command adjustment system 20 in the UAV 2. In one embodiment, the control command adjustment system 20 may include one or more modules, for example, a receiving module 201, an obtaining module 202, a calculation module 203, and an adjustment module 204. The one or more modules 201-204 may comprise computerized code in the form of one or more programs that are stored in the storage device 21 (or memory). The computerized code includes instructions that are executed by the at least one processor 26 to provide functions for the one or more modules 201-204.

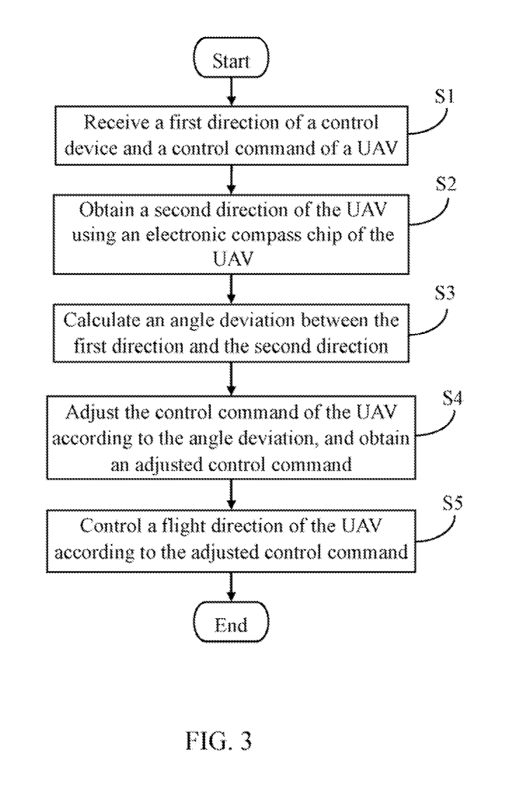

FIG. 3 is a flowchart of one embodiment of a method for adjusting a control command of the UAV 2 using the control device. Depending on the embodiment, additional blocks may be added, others removed, and the ordering of the blocks may be changed.

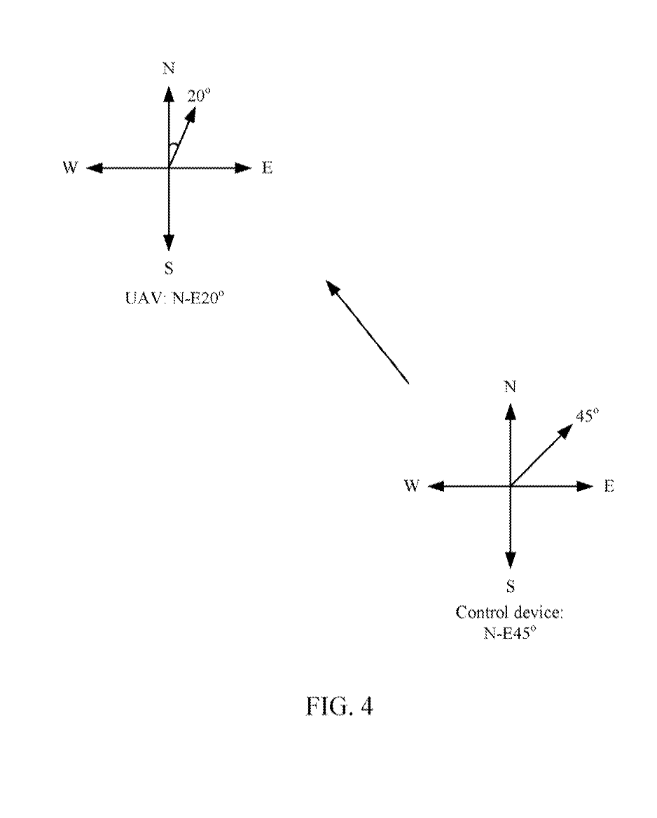

In block S1, the receiving module 201 receives a first direction of the control device and a control command of the UAV 2 using the signal receiver 25 through the network module 24. The first direction of the control device is obtained using an electronic compass chip installed in the control device. In one embodiment, the first direction of the control device includes a first cardinal direction, a first deflecting direction, and a first deflecting angle of the control device. As an example shown in FIG. 4, the first direction of the control device is north-east forty five degrees) (N-E45°). The first cardinal direction of the control device is towards north (“N”), the first deflecting direction of the control device is towards east (“E”), and the first deflecting angle of the control device is forty five degrees.

In block S2, the obtaining module 202 obtains a second direction of the UAV 2 using the electronic compass chip 22. In one embodiment, the second direction of the UAV 2 includes a second cardinal direction, a second deflecting direction, and a second deflecting angle of the UAV 2. As an example shown in FIG. 4, the second direction of the UAV 2 is north-east twenty degrees) (N-E20°). The second cardinal direction of the UAV 2 is towards north (“N”), the second deflecting direction of the UAV 2 is towards east (“E”), and the second deflecting angle of the UAV 2 is twenty degrees.

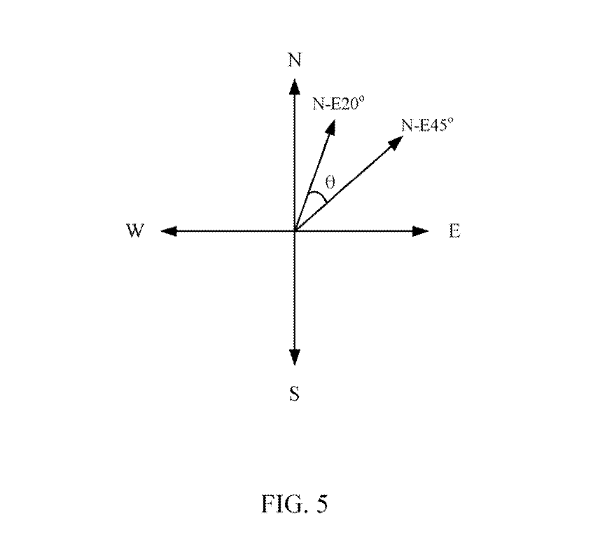

In block S3, the calculation module 203 calculates an angle deviation between the first direction of the control device and the second direction of the UAV 2. Referring to FIG. 5, “θ” represents the angle deviation between the first direction and the second direction, θ=45°−20°=25°.

In block S4, the adjustment module 204 adjusts a control command of the UAV 2 according to the angle deviation, and obtains an adjusted control command. In one embodiment, the control command is used to control a flight direction of the UAV 2. For example, the adjustment module 203 adjusts the second direction of the UAV 2 to the first direction of the control device according to the angle deviation. For example, as shown in FIG. 5, if an initial flight direction the control command of the UAV 2 is north, an adjusted flight direction of the adjusted control command is north-east twenty five degrees) (N-E25°).

In block S5, the adjustment module 204 controls the flight direction of the UAV 2 according to the adjusted control command.

In one embodiment, the control command adjustment system 20 is installed in the UAV 2, a direction of the control device and a control command of the UAV 2 are transmitted together from the control device to the UAV 2, the UAV 2 does not need to transmit any data to the control device. Thus, the data transmission between the UAV 2 and the control device is a one-way transmission.

In another embodiment, if the control command adjustment system 20 is installed in the control device, a flight direction of the UAV 2 is first transmitted to the control device. The control device adjusts a control command of the UAV 2 according to the flight direction of the UAV 2, and transmits an adjusted control command to the UAV 2 to control the flight direction of the UAV 2. Thus, the data transmission between the UAV 2 and the control device is a two-way transmission which increases the transmission load between the UAV 2 and the control device. That is to say, the one-way transmission is more efficient than the two-way transmission.

It should be emphasized that the above-described embodiments of the present disclosure, particularly, any embodiments, are merely possible examples of implementations, merely set forth for a clear understanding of the principles of the disclosure. Many variations and modifications may be made to the above-described embodiment(s) of the disclosure without departing substantially from the spirit and principles of the disclosure. All such modifications and variations are intended to be included herein within the scope of this disclosure and the present disclosure and protected by the following claims.

What is claimed is:

1. A method for adjusting a flight direction of an unmanned aerial vehicle using a control device, the method comprising:
receiving a first direction of the control device and a control command of the unmanned aerial vehicle (UAV);
obtaining a second direction of the UAV using an electronic compass chip of the UAV;
calculating an angle deviation between the first direction of the control device and the second direction of the UAV;
adjusting the control command of the UAV according to the angle deviation, and obtaining an adjusted control command; and
controlling a flight direction of the UAV according to the adjusted control command

2. The method according to claim 1, wherein the first direction of the control device comprises a first cardinal direction, a first deflecting direction, and a first deflecting angle of the control device.

3. The method according to claim 1, wherein the second direction of the UAV comprises a second cardinal direction, a second deflecting direction, and a second deflecting angle of the UAV.

4. The method according to claim 1, wherein the step of adjusting the control command of the UAV according to the angle deviation comprises: adjusting the second direction of the UAV to the first direction of the control device according to the angle deviation between the first direction and the second direction.

5. An unmanned aerial vehicle (UAV) in communication with a control device, comprising:
a storage device;
an electronic compass chip;
at least one processor; and
one or more modules that are stored in the storage device and are executed by the at least one processor, the one or more modules comprising instructions:
to receive a first direction of the control device and a control command of the unmanned aerial vehicle (UAV);
to obtain a second direction of the UAV using an electronic compass chip of the UAV;
to calculate an angle deviation between the first direction of the control device and the second direction of the UAV;
to adjust the control command of the UAV according to the angle deviation, and obtain an adjusted control command; and
to control a flight direction of the UAV according to the adjusted control command.

6. The UAV according to claim 5, wherein the first direction of the control device comprises a first cardinal direction, a first deflecting direction, and a first deflecting angle of the control device.

7. The UAV according to claim 5, wherein the second direction of the UAV comprises a second cardinal direction, a second deflecting direction, and a second deflecting angle of the UAV.

8. The UAV according to claim 5, wherein the instruction of adjusting the control command of the UAV according to the angle deviation comprises: adjusting the second direction of the UAV to the first direction of the control device according to the angle deviation between the first direction and the second direction.

9. A non-transitory storage medium having stored thereon instructions that, when executed by a processor of an unmanned aerial vehicle, causes the processor to perform a method for adjusting a flight direction of the unmanned aerial vehicle using a control device, the method comprising:
receiving a first direction of the control device and a control command of the unmanned aerial vehicle (UAV);
obtaining a second direction of the UAV using an electronic compass chip of the UAV;
calculating an angle deviation between the first direction of the control device and the second direction of the UAV;
adjusting the control command of the UAV according to the angle deviation, and obtaining an adjusted control command; and
controlling a flight direction of the UAV according to the adjusted control command

10. The non-transitory storage medium according to claim 9, wherein the first direction of the control device comprises a first cardinal direction, a first deflecting direction, and a first deflecting angle of the control device.

11. The non-transitory storage medium according to claim 9, wherein the second direction of the UAV comprises a second cardinal direction, a second deflecting direction, and a second deflecting angle of the UAV.

12. The non-transitory storage medium according to claim 9, wherein the step of adjusting the control command of the UAV according to the angle deviation comprises:
adjusting the second direction of the UAV to the first direction of the control device according to the angle deviation between the first direction and the second direction.

13. The non-transitory storage medium according to claim 9, wherein the medium is selected from the group consisting of a hard disk drive, a compact disc, a digital video disc, and a tape drive.
